(19) United States
(12) Patent Application Publication
(10) Pub. No.: US 2012/0292085 A1
(43) Pub. Date: Nov. 22, 2012

(54) FLEXIBLE PRINTED CIRCUIT AND METHOD OF MANUFACTURING THE SAME

(75) Inventor: Hirohito Watanabe, Sakura-shi (JP)

(73) Assignee: FUJIKURA LTD., Tokyo (JP)

(21) Appl. No.: 13/455,312

(22) Filed: Apr. 25, 2012

(30) Foreign Application Priority Data
May 19, 2011 (JP) 2011-112037

(51) Int. Cl. H05K 1/00; H05K 3/46

(52) U.S. Cl. 174/254; 156/182

(57) ABSTRACT

Provided is a flexible printed circuit having a multilayered structure including three conductive layers. The flexible printed circuit includes: a first unit substrate formed of a first insulating layer made of liquid crystal polymer or fluorine resin and having a signal transmission circuit formed on one surface of the first insulating layer and a first conductive layer formed on the other surface thereof; a second unit substrate formed of a second insulating layer made of liquid crystal polymer or fluorine resin and having a second conductive layer formed on one surface of the second insulating layer; and an adhesive layer made of an epoxy thermal curing adhesive for bonding the first unit substrate and the second unit substrate in a state that the one surface of the first insulating layer is faced with the other surface of the second insulating layer.

### CROSS REFERENCE TO RELATED APPLICATIONS

This application is based on and claims the benefit of priority from prior Japanese Patent Application No. 2011-112037, filed on May 19, 2011, the entire contents of which are incorporated herein by reference.

### BACKGROUND OF THE INVENTION

1. Field of the Invention

The present invention relates to a flexible printed circuit having a multilayered structure and a method of manufacturing the same.

2. Description of the Related Art

Flexible printed circuits using a wiring board such as a flexible printed board, etc. widely used for electronic parts, etc. include those having a multilayered structure for adapting to high-density packaging. Furthermore, flexible printed circuits using a base substrate made of liquid crystal polymer having a transmission loss lower than that of polyimide have also been produced to meet the recent demand for high-speed signal transmission.

For example, a wiring board disclosed in Unexamined Japanese Patent Application Publication No. 2010-219552 is known as a multilayered flexible printed circuit made of liquid crystal polymer. This wiring board is structured as a laminate of a plurality of liquid-crystal-polymer unit substrates on each of which a conductive layer is formed. These unit substrates are thermal-compression-bonded to each other after at least one surface of each of them is processed by plasma roughening. This allows for avoiding the use of an interlayer adhesive.

### SUMMARY OF THE INVENTION

However, although the wiring board disclosed in Unexamined Japanese Patent Application Publication No. 2010-219552 has an advantage of low transmission loss because it is made of liquid crystal polymer having a low dielectric constant, this wiring board, if manufactured so as to have a specific characteristic impedance, will have a circuit width larger than that of a conventional wiring board made of polyimide, which makes it difficult to achieve high-density packaging.

Furthermore, the wiring board disclosed in Unexamined Japanese Patent Application Publication No. 2010-219552, which is to be manufactured by melting the liquid crystal polymer at a melting start temperature of, for example, 250° C. or higher for thermal-compression-bonding the unit substrates, cannot be manufactured in an existing manufacturing facility in which it is assumed to use a thermal curing adhesive having a thermal curing temperature of approximately 160° C. Hence, a new facility investment is required, leading to a problem of cost increase. These problems will also occur when the wiring board is made of fluorine resin, like when it is made of liquid crystal polymer.

To solve the problems of the conventional techniques described above, an object of the present invention is to provide a flexible printed circuit which uses a thermal curing adhesive as an interlayer adhesive, realizes a smaller circuit width at a specific characteristic impedance at a low cost to allow high density packaging, and has an excellent high frequency characteristic, and a method of manufacturing the flexible printed circuit.

A flexible printed circuit according to one embodiment of the present invention is a flexible printed circuit board having a multilayered structure including three conductive layers, and includes: a first unit substrate having a first insulating layer made of liquid crystal polymer or fluorine resin, a signal transmission circuit formed on one surface of the first insulating layer and a first conductive layer formed on the other surface thereof; a second unit substrate having a second insulating layer made of liquid crystal polymer or fluorine resin and a second conductive layer formed on one surface of the second insulating layer; and an adhesive layer made of an epoxy thermal curing adhesive which bonds the first unit substrate and the second unit substrate in a state that the one surface of the first insulating layer is faced with the other surface of the second insulating layer.

In the flexible printed circuit according to one embodiment of the present invention, the first and second insulating layers of the first and second unit substrates are made of liquid crystal polymer or fluorine resin having a low dielectric constant and a low dielectric tangent, and they are bonded by an epoxy thermal curing adhesive having a dielectric constant higher than that of liquid crystal polymer or fluorine resin. Therefore, the flexible printed circuit has a structure that can realize the same characteristic impedance as a specific characteristic impedance by using substrates having a circuit width smaller than conventional. This structure allows substrates having an excellent high-frequency characteristic to be packaged with a higher density.

Further, because it is possible to bond the first and second unit substrates by curing the thermal curing adhesive at a curing temperature of approximately 160° C., it is possible to use an existing manufacturing facility to manufacture them, which makes it possible to manufacture a high-density flexible printed circuit having an excellent high-frequency characteristic at a low cost.

In another embodiment of the present invention, the curing temperature of the thermal curing adhesive is lower than the melting points of the first and second insulating layers.

In yet another embodiment of the present invention, the first and second unit substrates are made of liquid crystal polymer.

In yet another embodiment of the present invention, the distance from a principal surface of the signal transmission circuit to the other surface of the second insulating layer is set in a range of 2 μm to 15 μm.

In yet another embodiment of the present invention, the circuit width of the signal transmission circuit is set in a range of 69 μm to 74 μm.

In yet another embodiment of the present invention, the first and second conductive layers are supplied with a reference potential.

In yet another embodiment of the present invention, the first unit substrate includes wiring circuits which are formed at both sides of the signal transmission circuit on the one surface of the first insulating layer and supplied with a reference potential.

A method of manufacturing a flexible printed circuit according to one embodiment of the present invention is a method of manufacturing a flexible printed circuit having a multilayered structure including three conductive layers, and includes: manufacturing a first unit substrate by forming a conductive layer to constitute a signal transmission circuit on one surface of a first insulating layer made of liquid crystal polymer or fluorine resin and forming a first conductive layer on the other surface thereof; and thermal-compression-bonding a second unit substrate formed of a second insulating layer made of liquid crystal polymer or fluorine resin and having a second conductive layer formed on one surface of the second insulating layer with the first unit substrate by positioning them such that the one surface of the first insulating layer is faced with the other surface of the second insulating layer, and interposing an adhesive layer made of an epoxy thermal curing adhesive between the faced surfaces.

In one embodiment of the present invention, in the thermal-compression-bonding, thermal compression bonding is performed at a temperature equal to or higher than the curing temperature of the adhesive layer and lower than the melting points of the first and second insulating layers.

### EFFECTS OF THE INVENTION

According to the present invention, it is possible to provide a flexible printed circuit which uses a thermal curing adhesive as an interlayer adhesive, realizes a smaller circuit width at a specific characteristic impedance at a low cost to allow high density packaging, and has an excellent high frequency characteristic, and a method of manufacturing the flexible printed circuit.

### BRIEF DESCRIPTION OF THE DRAWINGS

FIG. 1A is a cross-sectional diagram showing a step of manufacturing a flexible printed circuit according to a first embodiment of the present invention.

FIG. 1B is a cross-sectional diagram showing a step of manufacturing the flexible printed circuit according to the first embodiment of the present invention.

FIG. 1C is a cross-sectional diagram showing a step of manufacturing the flexible printed circuit according to the first embodiment of the present invention.

FIG. 1D is a cross-sectional diagram showing a step of manufacturing the flexible printed circuit according to the first embodiment of the present invention.

FIG. 2 is a flowchart showing the steps of manufacturing the flexible printed circuit.

FIG. 3 is a cross-sectional diagram showing a flexible printed circuit according to an example of the present invention.

FIG. 4 is a diagram showing the details of each sample of the flexible printed circuit according to the example.

FIG. 5 is a diagram showing the result of measurement of characteristic impedance of each sample of the flexible printed circuit according to the example.

FIG. 6 is a diagram showing a relationship between the circuit width at which the characteristic impedance of each sample of the flexible printed circuit according to the example is 50Ω and the thickness of a specific portion of an adhesive layer.

FIG. 7 is a diagram showing the result of measurement of transmission loss of each sample of the flexible printed circuit according to the example.

FIG. 8 is a diagram showing a relationship between the transmission loss of each sample of the flexible printed circuit according to the example and the thickness of a specific portion of an adhesive layer.

FIG. 9 is a diagram showing a relationship between the transmission loss ratio of each sample of the flexible printed circuit according to the example and the thickness of a specific portion of an adhesive layer.

### DETAILED DESCRIPTION OF THE EMBODIMENTS

A flexible printed circuit and a method of manufacturing the same according to the present invention will now be explained with reference to the drawings.

### First Embodiment

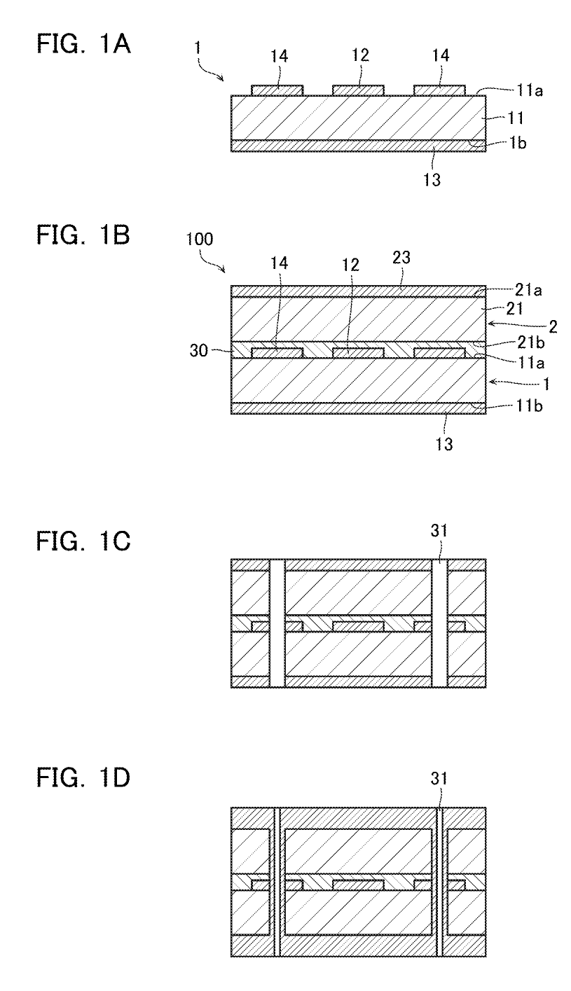

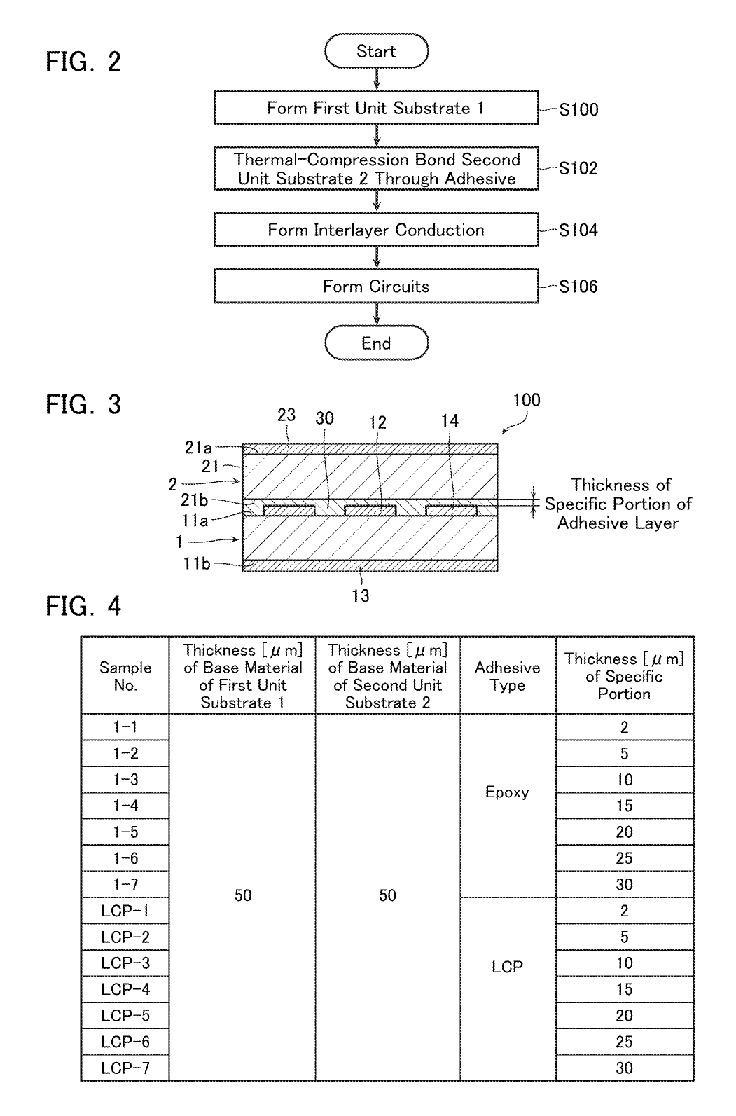

FIG. 1A, FIG. 1B, FIG. 1C, and FIG. 1D are cross-sectional diagrams showing manufacturing steps of a method of manufacturing a flexible printed circuit according to the first embodiment of the present invention. FIG. 2 is a flowchart showing the manufacturing steps.

A flexible printed circuit (hereinafter referred to as “FPC”) 100 according to the first embodiment (see FIG. 1B) is manufactured as follows. First, as shown in FIG. 1A and FIG. 2, a first unit substrate 1 is formed (step S100). The first unit substrate 1 includes a first insulating layer 11 having a thickness of, for example, 50 μm and made of liquid crystal polymer (LCP) or fluorine resin.

The first unit substrate 1 includes a signal transmission circuit 12 formed on one surface 11a of the first insulating layer 11 and a first conductive layer 13 formed on the other surface 11b thereof. The signal transmission circuit 12 and the first conductive layer 13 are made of an electrolytic copper foil having a thickness of, for example, 18 μm. In step S100, the signal transmission circuit 12 is formed on one surface of a copper-clad laminate having copper foils on both surfaces.

Next, as shown in FIG. 1B and FIG. 2, a second unit substrate 2 is thermal-compression bonded to the first unit substrate 1 through an adhesive (step S102). Like the first unit substrate 1, the second unit substrate 2 includes a second insulating layer 21 having a thickness of, for example, 50 μm and made of liquid crystal polymer or fluorine resin. The second unit substrate 2 includes, on one surface 21a of the second insulating layer 21, a second conductive layer 23 made of an electrolytic copper foil having a thickness of, for example, 18 μm like the first conductive layer 13.

The adhesive constituting an adhesive layer 30 is an epoxy thermal curing adhesive. In step S102, the first unit substrate 1 and the second unit substrate 2 are thermal-compression-bonded by positioning them such that the surface 11a of the first unit substrate 1 and a surface 21b of the second unit substrate 2 are faced with each other, and forming the adhesive layer 30 between them by applying or filling an epoxy thermal curing adhesive between them.

The curing temperature of the thermal curing adhesive is set to a temperature equal to or higher than, for example, 160° C., and lower than the melting points (for example, 310° C.) of the first and second insulating layers 11 and 21. Hence, in step S102, thermal compression bonding is performed at a heating temperature (for example, 200° C.) equal to or higher than the curing temperature of the adhesive layer 30 and lower than the melting points of the first and second insulating layers 11 and 21.

Thereby, the signal transmission circuit 12 is positioned between the first insulating layer 11 of the first unit substrate 1 and the second insulating layer 21 of the second unit substrate 2. Next, after step S102, in the case of the FPC 100 according to the first embodiment, through-holes 31 are formed so as to penetrate the first and second unit substrates 1 and 2 and also penetrate wiring circuits 14 which are formed along a principal surface of the first insulating layer 11 to adjoin the signal transmission circuit 12 at both sides thereof, as shown in FIG. 1C and FIG. 2.

Then, the through-holes 31 are plated, and the first and second conductive layers 13 and 23 and the wiring circuits 14 are electrically connected to form interlayer conduction as shown in FIG. 1D and FIG. 2 (step S104), predetermined circuits (unillustrated) are formed on the first and second conductive layers 13 and 23 (step S106), and thus the FPC 100 is completed. Because the first and second conductive layers 13 and 23 are supplied with a reference potential (a power supply potential, a ground potential), the wiring circuits 14 also become the reference potential.

The FPC 100 manufactured in this way includes the signal transmission circuit 12 in a so-called inner layer, and realizes a structure in which the signal transmission circuit 12 is sandwiched between the first and second conductive layers 13 and 23 which are located more outward than the signal transmission circuit 12. Hence, it is possible to prevent EMC (Electromagnetic Compatibility) and EMI (Electromagnetic Interference).

It should be noted that because the adhesive layer 30 is made of an epoxy thermal curing adhesive, there is a fear that if the adhesive layer 30 is used without concern, a high dielectric constant and a high dissipation factor of the adhesive layer 30 might contribute to a transmission loss of the FPC 100, as explained in the description of the conventional art. However, the applicant has discovered in an experiment that the influence of the adhesive layer 30 is trivial if the thickness of a specific portion of the adhesive layer 30 is in a predetermined range.

### EXAMPLE

The FPC 100 will now be specifically explained based on an example. FIG. 3 is a cross-sectional diagram showing an FPC 100 according to an example of the present invention. As shown in FIG. 3, the thickness of a specific portion of the adhesive layer 30 is defined by the distance between a principal surface of the signal transmission circuit 12 on the first unit substrate 1 and the other surface 21b of the second unit substrate 2. That is, the thickness of the specific portion of the adhesive layer is the distance between the interface between the signal transmission circuit 12 and the adhesive layer 30 and the interface between the second insulating layer 21 and the adhesive layer 30. According to an experiment conducted by the applicant, the thickness of the specific portion of the adhesive layer is determined in the range of 2 μm to 15 μm.

In such a range, it is possible to achieve a transmission loss equal to or lower than 1.3 times of a transmission loss achieved when the unit substrates are bonded through the liquid crystal polymer without using an interlayer adhesive. Hence, even though the FPC 100 according to the present invention is manufactured by thermal-compression-bonding the first and second unit substrates 1 and 2 through the adhesive layer 30, it can reduce the transmission loss difference.

In the present example, sample FPCs 100 were manufactured by using a liquid crystal polymer flexible copper-clad laminate “FELIOS R-F705Z (product name)” having an excellent high-speed transmission characteristic, which is provided by Panasonic Corporation. These samples include those prepared for the measurement of characteristic impedance and those prepared for the measurement of loss.

As shown in FIG. 4, in the samples Nos. 1-1 to 1-7, the thickness of the first and second insulating layers (base materials) 11 and 21 of the first and second unit substrates 1 and 2 was 50 μm respectively, and the type of the adhesive was epoxy. The thickness of the specific portion of the adhesive layer was set to 2, 5, 10, 15, 20, 25, and 30 μm, respectively.

In the samples Nos. LCP-1 to LCP-7, the thickness of the first and second insulating layers 11 and 21 of the first and second unit substrates 1 and 2 was likewise 50 μm respectively. However, the adhesive layer 30 was made of liquid crystal polymer having a melting point lower than that of the liquid crystal polymer used for the first and second insulating layers 11 and 21 by 30° C. The thickness of the specific portion of the adhesive layer was also set to 2, 5, 10, 15, 20, 25, and 30 μm, respectively.

For each of the samples described above, fifty-one products were prepared by varying their circuit width from 50 μm to 100 μm at the intervals of 1 μm, and the characteristic impedance of each product was measured by using a TDR (Time Domain Reflectometry) module “80E04 (product name)” and a sampling oscilloscope “DSA8200 (product name)”, which are provided by Tektronix, Inc.

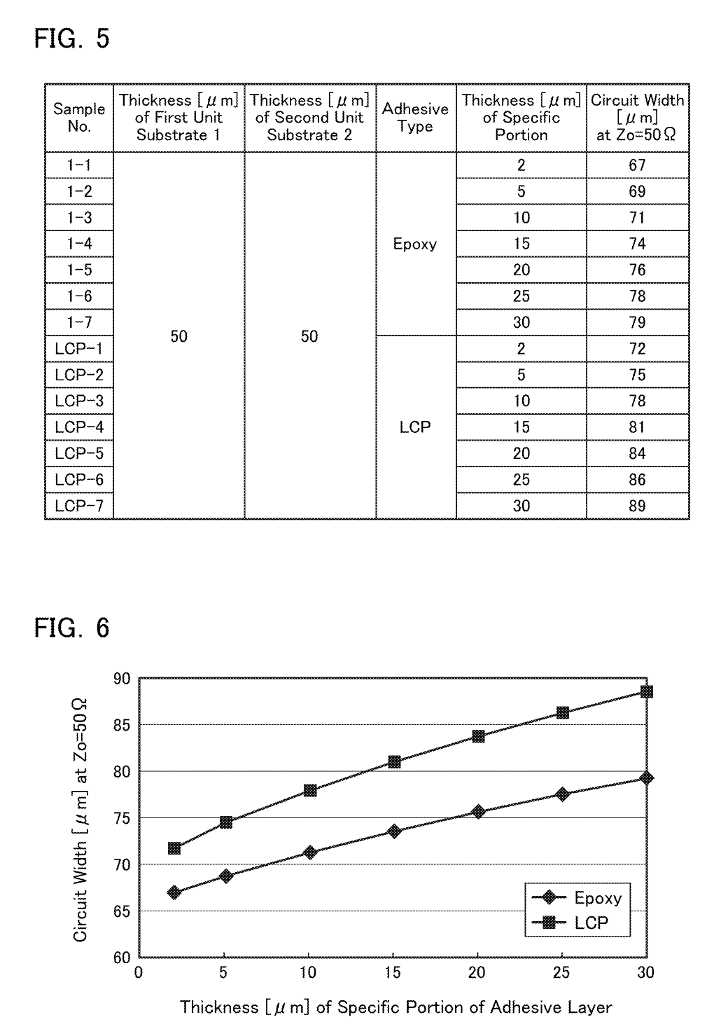

FIG. 5 and FIG. 6 show the result of researching the circuit width at which the characteristic impedance of each sample was 50Ω, based on the result of the measurement. Note that where the characteristic impedance Zo is defined as Zo=\sqrt{L/C} and capacitance C is defined as C=εr·εo·S/d, it is required as a prerequisite that the respective samples should have the same capacitance C in order to have the same characteristic impedance Zo.

As shown in FIG. 5, in the samples Nos. 1-1 to 1-7 and LCP-1 to LCP-7, the larger the thickness of the specific portion of the adhesive layer was, the larger the distance between the signal transmission circuit 12 and the second conductive layer 23, which was, for example, at a ground potential, was, and hence the larger the circuit width at the time of the design for the characteristic impedance Zo=50Ω was. This is also obvious from the above prerequisite which indicates that it is possible to achieve the same capacitance C by increasing S (circuit width) by what corresponds to an increase of d (distance), and that it is possible to achieve the same characteristic impedance Zo by achieving the same capacitance C.

Further, when comparing the case when the adhesive layer 30 was made of the epoxy thermal curing adhesive and the case when it was made of liquid crystal polymer, the circuit width at the time of the design for the characteristic impedance Zo=50Ω was larger when the adhesive layer 30 was made of liquid crystal polymer having a lower dielectric constant. This is also obvious from the above prerequisite which indicates that S (circuit width) needs to be increased in accordance with how much the relative permittivity εr is lower by ratio, provided that the samples have the same value for d (distance).

Furthermore, when the epoxy thermal curing adhesive was used, the circuit width at the time of the design for the characteristic impedance Zo=50Ω could be smaller by approximately 5 μm to 10 μm than when the liquid crystal polymer was used, as for each thickness of the specific portion of the adhesive layer, as shown in FIG. 6. This is also obvious from the above prerequisite which indicates that S (circuit width) needs to be reduced in accordance with how much the relative permittivity εr is higher by ratio, provided that the samples have the same value for d (distance).

As can be understood from the above, it turned out that the sample FPCs 100 according to the present invention identified by sample Nos. 1-1 to 1-7 could have smaller circuit widths, when it was attempted to realize the same characteristic impedance Zo between when the epoxy thermal curing agent is used as the adhesive layer 30 and when liquid crystal polymer is used. Therefore, it is possible to be packaged with a high density.

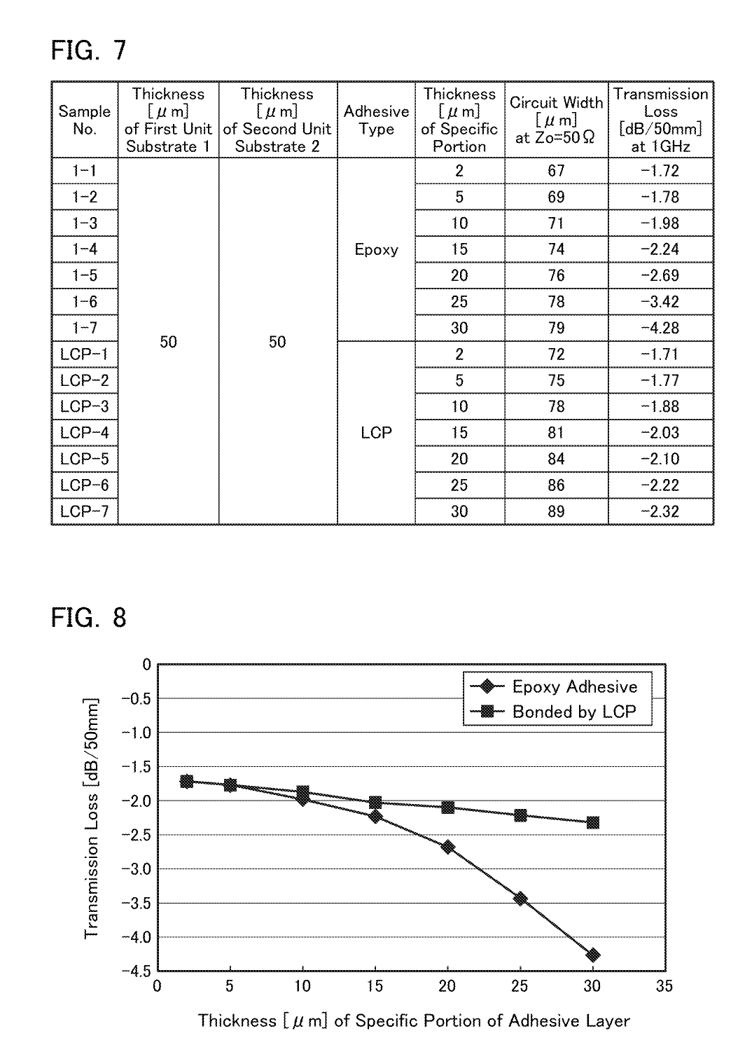

Next, the transmission loss of the circuit at the time of the design for the characteristic impedance Zo=50Ω was measured for each of the above samples by using a vector network analyzer “PNA-L Network Analyzer N5230A (product name)” provided by Agilent Technologies. FIG. 7 and FIG. 8 show the result of the measurement.

As regards the transmission loss, when the epoxy thermal curing adhesive was used as the adhesive layer 30, there was a tendency that the transmission loss was a bit higher than when the liquid crystal polymer was used, especially as the thickness of the specific portion of the adhesive layer increased. However, it turned out that the influence of the transmission loss was trivial when the thickness of the specific portion of the adhesive layer was relatively small, falling within a predetermined range.

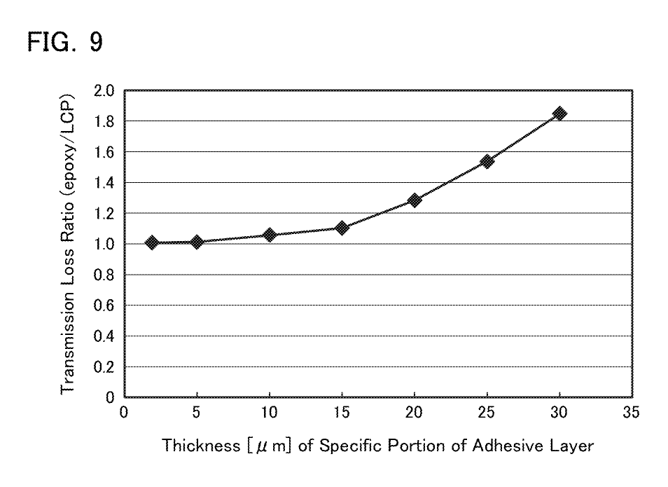

FIG. 9 shows the result of comparison of the transmission loss between when the epoxy thermal curing adhesive was used as the adhesive layer 30 and when the liquid crystal polymer was used, between the samples in which the thickness of the specific portion of the adhesive layer was the same. According to this, the transmission loss difference between the samples was as small as 10% or lower, where the thickness of the specific portion of the adhesive layer was in the range of 2 μm to 15 μm.

Hence, it turned out that even if the epoxy thermal curing adhesive is used as the adhesive layer 30, it is possible to achieve a transmission characteristic comparable to that achieved when the liquid crystal polymer is used, as long as the thickness of the specific portion of the adhesive layer is in the above range. Hence, according to the FPC 100 according to the embodiment described above, even if the epoxy thermal curing adhesive is used as the adhesive layer 30, the transmission loss can be suppressed substantially as well as when the liquid crystal polymer is used, as long as the thickness of the specific portion of the adhesive layer is set appropriately in accordance with the characteristic impedance required.

For example, when the FPC 100 is used as a transmission cable between an antenna circuit and a transmission/reception circuit, it is generally preferred that the transmission loss of the FPC 100 be suppressed to 3 dB or lower. Also in this case, the FPC 100 can fairly meet the transmission loss required, as long as the thickness of the specific portion of the adhesive layer is adjusted appropriately.

What is claimed is:

1. A flexible printed circuit having a multilayered structure including three conductive layers, comprising:
a first unit substrate having a first insulating layer made of liquid crystal polymer or fluorine resin, a signal transmission circuit formed on one surface of the first insulating layer and a first conductive layer formed on the other surface thereof;
a second unit substrate having a second insulating layer made of liquid crystal polymer or fluorine resin and a second conductive layer formed on one surface of the second insulating layer; and
an adhesive layer made of an epoxy thermal curing adhesive which bonds the first unit substrate and the second unit substrate in a state that the one surface of the first insulating layer is faced with the other surface of the second insulating layer.

2. The flexible printed circuit according to claim 1,
wherein a curing temperature of the thermal curing adhesive is lower than melting points of the first and second insulating layers.

3. The flexible printed circuit according to claim 1,
wherein the first and second unit substrates are made of liquid crystal polymer.

4. The flexible printed circuit according to claim 3,
wherein a distance from a principal surface of the signal transmission circuit to the other surface of the second insulating layer is set in a range of 2 μm to 15 μm.

5. The flexible printed circuit according to claim 4,
wherein a circuit width of the signal transmission circuit is set in a range of 69 μm to 74 μm.

6. The flexible printed circuit according to claim 1,
wherein the first and second conductive layers are supplied with a reference potential.

7. The flexible printed circuit according to claim 1,
wherein the first unit substrate includes wiring circuits which are formed at both sides of the signal transmission circuit on the one surface of the first insulating layer and supplied with a reference potential.

8. A method of manufacturing a flexible printed circuit having a multilayered structure including three conductive layers, the method comprising:
manufacturing a first unit substrate by forming a signal transmission circuit on one surface of a first insulating layer made of liquid crystal polymer or fluorine resin and forming a first conductive layer on the other surface thereof; and
thermal-compression-bonding a second unit substrate formed of a second insulating layer made of liquid crystal polymer or fluorine resin and having a second conductive layer formed on one surface of the second insulating layer with the first unit substrate by positioning them such that the one surface of the first insulating layer is faced with the other surface of the second insulating layer, and interposing an adhesive layer made of an epoxy thermal curing adhesive between the faced surfaces.

9. The method of manufacturing a flexible printed circuit according to claim 8,
wherein in the thermal-compression-bonding, thermal compression bonding is performed at a temperature equal to or higher than a curing temperature of the adhesive layer and lower than melting points of the first and second insulating layers.
